(19) United States
(12) Patent Application Publication
(10) Pub. No.: US 2026/0068307 A1
(43) Pub. Date: Mar. 5, 2026

(54) STACKED TRANSISTORS WITH WORK FUNCTION MATERIAL

(71) Applicant: International Business Machines Corporation, Armonk, NY (US)

(72) Inventors: Debarghya Sarkar, Latham, NY (US); Ruilong Xie, Niskayuna, NY (US); Takashi Ando, Eastchester, NY (US); Nicholas Anthony Lanzillo, Wynantskill, NY (US); Brent Alan Anderson, Jericho, VT (US); Chen Zhang, Santa Clara, CA (US); Shay Reboh, Guilderland, NY (US)

(21) Appl. No.: 18/825,254

(22) Filed: Sep. 5, 2024

(51) Int. Cl. H01L 27/092; H01L 21/28; H01L 21/822; H01L 21/8238; H01L 29/06; H01L 29/423; H01L 29/49; H01L 29/66; H01L 29/775; H01L 29/786

(52) U.S. Cl. CPC H10D 84/856; H10D 30/014; H10D 30/43; H10D 30/6735; H10D 30/6739; H10D 30/6757; H10D 62/121; H10D 84/0177; H10D 84/038; H10D 88/01

(57) ABSTRACT

Embodiments include a semiconductor structure having a first lower transistor and a second lower transistor. Upper transistors are formed above the first and second lower transistors, the first lower transistor having a first work function material, the second lower transistor having a second work function material different from the first work function material. A portion of the second work function material extends below a bottom surface of the first work function material.

### BACKGROUND

The present invention generally relates to fabrication methods and resulting structures for integrated circuits (ICs), and more specifically, to fabrication methods and resulting structures configured and arranged for providing stacked transistors with work function material/metal fill from both the frontside and backside.

ICs (also referred to as a chip or a microchip) include electronic circuits on a wafer. The wafer is a semiconductor material, such as, for example, silicon or other materials. An IC is formed of a large number of devices, such as transistors, capacitors, resistors, etc., which are formed in layers of the IC and interconnected with wiring in the back-end-of-line (BEOL) layers of the wafer. on the wafer. Typical ICs are formed by first fabricating individual semiconductor devices using processes referred to generally as the front-end-of-line (FEOL). A metal-oxide-semiconductor field-effect transistor (MOSFET) is a transistor used for amplifying or switching electronic signals. The MOSFET has a source, a drain, and a metal oxide gate electrode. A conventional FET is a planar device where the entire channel region of the device is formed parallel and slightly below the planar upper surface of the semiconducting substrate. In contrast to a planar FET, there are so-called three-dimensional (3D) devices, such as a FinFET device, which is a three-dimensional structure. One type of device that for advanced integrated circuit products is generally known as a nanosheet transistor. In general, a nanosheet transistor has a fin-type channel structure that includes a plurality of vertically spaced-apart sheets of semiconductor material. A gate structure for the device is positioned around each of these spaced-apart layers of channel semiconductor material.

### SUMMARY

Embodiments of the present invention are directed to providing stacked transistors with work function material/metal fill from both frontside and backside. A semiconductor structure includes a first lower transistor and a second lower transistor. The semiconductor structure includes upper transistors formed above the first and second lower transistors, the first lower transistor including a first work function material, the second lower transistor including a second work function material different from the first work function material. A portion of the second work function material extends below a bottom surface of the first work function material.

According to one or more embodiments, a method includes providing a first lower transistor and a second lower transistor. The method includes forming upper transistors on a frontside of the semiconductor structure above the first and second lower transistors, the first lower transistor including a first work function material, the second lower transistor including a second work function material different from the first work function material. The second work function material is filled from a backside of the semiconductor structure.

Other embodiments of the present invention implement features of the above-described devices/structures in methods and/or implement features of the methods in devices/structures.

Additional technical features and benefits are realized through the techniques of the present invention. Embodiments and aspects of the invention are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the invention are apparent from the following detailed description taken in conjunction with the accompanying drawings in which:

FIGS. 1A, 1B, 1C, 1D, and 1E respectively depict a top view and cross-sectional views of a portion of an integrated circuit (IC) under-fabrication after fabrication operations according to one or more embodiments of the invention;

FIGS. 2A, 2B, 2C, 2D, and 2E depict a top view and cross-sectional views of a portion of an IC under-fabrication after fabrication operations according to one or more embodiments of the invention;

FIGS. 3A, 3B, 3C, 3D, and 3E depict a top view and cross-sectional views of a portion of an IC under-fabrication after fabrication operations according to one or more embodiments of the invention;

FIGS. 4A, 4B, 4C, 4D, and 4E depict a top view and cross-sectional views of a portion of an IC under-fabrication after fabrication operations according to one or more embodiments of the invention;

FIGS. 5A, 5B, 5C, 5D, and 5E depict a top view and cross-sectional views of a portion of an IC under-fabrication after fabrication operations according to one or more embodiments of the invention;

FIGS. 6A, 6B, 6C, 6D, and 6E depict a top view and cross-sectional views of a portion of an IC under-fabrication after fabrication operations according to one or more embodiments of the invention;

FIGS. 7A, 7B, 7C, 7D, and 7E depict a top view and cross-sectional views of a portion of an IC under-fabrication after fabrication operations according to one or more embodiments of the invention;

FIGS. 8A, 8B, 8C, 8D, and 8E depict a top view and cross-sectional views of a portion of an IC under-fabrication after fabrication operations according to one or more embodiments of the invention;

FIGS. 9A, 9B, 9C, 9D, and 9E depict a top view and cross-sectional views of a portion of an IC under-fabrication after fabrication operations according to one or more embodiments of the invention;

FIGS. 10A, 10B, 10C, 10D, and 10E depict a top view and cross-sectional views of a portion of an IC under-fabrication after fabrication operations according to one or more embodiments of the invention;

FIGS. 11A, 11B, 11C, 11D, and 11E depict a top view and cross-sectional views of a portion of an IC under-fabrication after fabrication operations according to one or more embodiments of the invention;

FIGS. 12A, 12B, 12C, 12D, and 12E depict a top view and cross-sectional views of a portion of an IC under-fabrication after fabrication operations according to one or more embodiments of the invention; and

FIG. 13 depicts a flowchart of a method of forming a semiconductor structure according to one or more embodiments of the invention.

### DETAILED DESCRIPTION

Embodiments of the present disclosure are directed to a semiconductor structure having a first lower transistor and a second lower transistor. The semiconductor structure includes upper transistors formed above the first and second lower transistors, the first lower transistor including a first work function material, the second lower transistor including a second work function material different from the first work function material. A portion of the second work function material extends below a bottom surface of the first work function material. As technical effects and technical solutions, the present disclosure provides the first lower transistor, the second lower transistor, and the upper transistors with different threshold voltages. By having the second work function material of the second lower transistor filled from the backside, the second work function material can avoid the high temperatures caused by forming the upper transistors such that the second lower transistor can maintain a super-low threshold voltage without being shifted, i.e., without increasing. This allows stacked transistors to have multiple threshold voltages including a super-low threshold voltage in one of the lower transistors in the stacked transistors.

In addition to one or more of the features described above or below, or as an alternative, further embodiments disclose the upper transistors include a third work function material different from the second work function material. Technical effects and solutions enable the stacked transistors to have multiple threshold voltages.

In addition to one or more of the features described above or below, or as an alternative, further embodiments disclose a gate connector connects one of the upper transistors to the second lower transistor, a part of the gate connector including the second work function material. Technical effects and solutions allow shared gate control for stacked transistors.

In addition to one or more of the features described above or below, or as an alternative, further embodiments disclose a gate connector connects one of the upper transistors to the second lower transistor, the gate connector including the second work function material and a third work function material of the one of the upper transistors. Technical effects and solutions allow shared gate control for stacked transistors.

In addition to one or more of the features described above or below, or as an alternative, further embodiments disclose the second lower transistor includes a gate dielectric material, an opening being in the gate dielectric material of the second lower transistor. Technical effects and solutions enable the stacked transistors to have multiple threshold voltages by filling from the backside to avoid high temperatures when forming upper transistors.

In addition to one or more of the features described above or below, or as an alternative, further embodiments disclose the second work function material is disposed in the opening of the second lower transistor. Technical effects and solutions enable the stacked transistors to have multiple threshold voltages by filling the second work function material from the backside after avoiding high temperatures of forming upper transistors.

In addition to one or more of the features described above or below, or as an alternative, further embodiments disclose the second work function material extends through the opening of the second lower transistor. Technical effects and solutions enable the stacked transistors to have multiple threshold voltages by filling the second work function material from the backside after avoiding high temperatures of forming upper transistors.

Embodiments of the present disclosure are directed to a method including providing a first lower transistor and a second lower transistor. The method includes forming upper transistors above the first and second lower transistors, the first lower transistor including a first work function material, the second lower transistor including a second work function material different from the first work function material. A portion of the second work function material extends below a bottom surface of the first work function material. As technical effects and technical solutions, the present disclosure provides the first lower transistor, the second lower transistor, and the upper transistors with different threshold voltages. By having the second work function material of the second lower transistor filled from the backside, the second work function material can avoid the high temperatures caused by forming the upper transistors such that the second lower transistor can maintain a super-low threshold voltage without being shifted, i.e., without increasing. This allows stacked transistors to have multiple threshold voltages including a super-low threshold voltage in one of the lower transistors in the stacked transistors.

In addition to one or more of the features described above or below, or as an alternative, further embodiments disclose the upper transistors include a third work function material different from the second work function material. Technical effects and solutions enable the stacked transistors to have multiple threshold voltages.

In addition to one or more of the features described above or below, or as an alternative, further embodiments disclose a gate connector connects one of the upper transistors to the second lower transistor, a part of the gate connector including the second work function material. Technical effects and solutions allow shared gate control for stacked transistors.

In addition to one or more of the features described above or below, or as an alternative, further embodiments disclose a gate connector connects one of the upper transistors to the second lower transistor, the gate connector including the second work function material and a third work function material of the one of the upper transistors. Technical effects and solutions allow shared gate control for stacked transistors.

In addition to one or more of the features described above or below, or as an alternative, further embodiments disclose the second lower transistor includes a gate dielectric material, an opening being in the gate dielectric material of the second lower transistor. Technical effects and solutions enable the stacked transistors to have multiple threshold voltages by filling from the backside to avoid high temperatures when forming upper transistors.

In addition to one or more of the features described above or below, or as an alternative, further embodiments disclose the second work function material is disposed in the opening of the second lower transistor. Technical effects and solutions enable the stacked transistors to have multiple threshold voltages by filling the second work function material from the backside after avoiding high temperatures of forming upper transistors.

In addition to one or more of the features described above or below, or as an alternative, further embodiments disclose the second work function material extends through the opening of the second lower transistor. Technical effects and solutions enable the stacked transistors to have multiple threshold voltages by filling the second work function material from the backside after avoiding high temperatures of forming upper transistors.

Embodiments of the present disclosure are directed to a method of forming a semiconductor structure. The method includes providing a first lower transistor and a second lower transistor. The method includes forming upper transistors on a frontside of the semiconductor structure above the first and second lower transistors, the first lower transistor including a first work function material, the second lower transistor including a second work function material different from the first work function material. The second work function material is filled from a backside of the semiconductor structure. As technical effects and technical solutions, the present disclosure provides the first lower transistor, the second lower transistor, and the upper transistors with different threshold voltages. By having the second work function material of the second lower transistor filled from the backside, the second work function material can avoid the high temperatures caused by forming the upper transistors such that the second lower transistor can maintain a super-low threshold voltage without being shifted, i.e., without increasing. This allows stacked transistors to have multiple threshold voltages including a super-low threshold voltage in one of the lower transistors in the stacked transistors.

In addition to one or more of the features described above or below, or as an alternative, further embodiments disclose the second lower transistor has a super-low threshold voltage, the first lower transistor has a medium threshold voltage, and the upper transistors have a high threshold voltage. Technical effects and solutions enable the stacked transistors to have multiple threshold voltages.

In addition to one or more of the features described above or below, or as an alternative, further embodiments disclose a gate connector connects one of the upper transistors to the second lower transistor, a part of the gate connector having the second work function material. Technical effects and solutions allow shared gate control for stacked transistors.

In addition to one or more of the features described above or below, or as an alternative, further embodiments disclose a gate connector connects the one of the upper transistors to the second lower transistor, the gate connector including the second work function material and a third work function material of the one of the upper transistors. Technical effects and solutions allow shared gate control for stacked transistors.

In addition to one or more of the features described above or below, or as an alternative, further embodiments disclose the second lower transistor includes a gate dielectric material, an opening being in the gate dielectric material of the second lower transistor, and the second work function material is disposed in the opening of the second lower transistor. Technical effects and solutions enable the stacked transistors to have multiple threshold voltages by filling from the backside to avoid high temperatures when forming upper transistors.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

The MOSFET is a transistor used for amplifying or switching electronic signals. The MOSFET has a source, a drain, and a metal gate electrode. The metal gate is electrically insulated from the main semiconductor n-channel or p-channel by a thin layer of insulating material, for example, silicon dioxide or glass, which makes the input resistance of the MOSFET relatively high. The gate voltage controls whether the current path from the source to the drain is an open circuit (“off”) or a resistive path (“on”). N-type field effect transistors (NFET) and p-type field effect transistors (PFET) are two types of complementary MOSFETs. The NFET includes n-doped source and drain junctions and uses electrons as the current carriers. The PFET includes p-doped source and drain junctions and uses holes as the current carriers.

The nanowire or nanosheet MOSFET is a type of MOSFET that uses multiple stacked nanowires/nanosheets to form multiple channel regions. The gate regions of a nanosheet MOSFET are formed by wrapping gate stack materials around the multiple nanowire/nanosheet channels. This configuration is known as a gate-all-around (GAA) FET structure. The nanowire/nanosheet MOSFET device mitigates the effects of short channels and reduces drain-induced barrier lowering.

The GAA nanosheet FET structures can provide superior electrostatics. In contrast to known Fin-type FET (FinFET) structures in which the fin element of the transistor extends “up” out of the transistor, nanosheet FET designs implement the fin as a silicon nanosheet/nanowire. In a known configuration of a GAA nanosheet FET, a relatively small FET footprint is provided by forming the channel region as a series of nanosheets (i.e., silicon nanowires). A known GAA configuration includes a source region, a drain region, and stacked nanosheet channels between the source and drain regions. A gate surrounds the stacked nanosheet channels and regulates electron flow through the nanosheet channels between the source and drain regions. GAA nanosheet FETs are fabricated by forming alternating layers of channel nanosheets and sacrificial nanosheets. The sacrificial nanosheets are released from the channel nanosheets before the FET device is finalized.

For next generation stacked transistors (stacked FETs), the sequential fabrication flow is from the front up. Although many threshold voltages for bottom transistors can sustain the thermal temperatures of top transistor fabrication, super-low threshold voltage (SLVT) transistors are affected by top transistor fabrication. One or more embodiments provide stacked transistors with work function material/metal fill from both the frontside and backside. As such, filing one or more bottom transistors with work function material from the backside subsequent to the high temperatures used to form the top transistors allows the bottom transistors to have the super-low threshold voltage without being impacted, according to one or more embodiments.

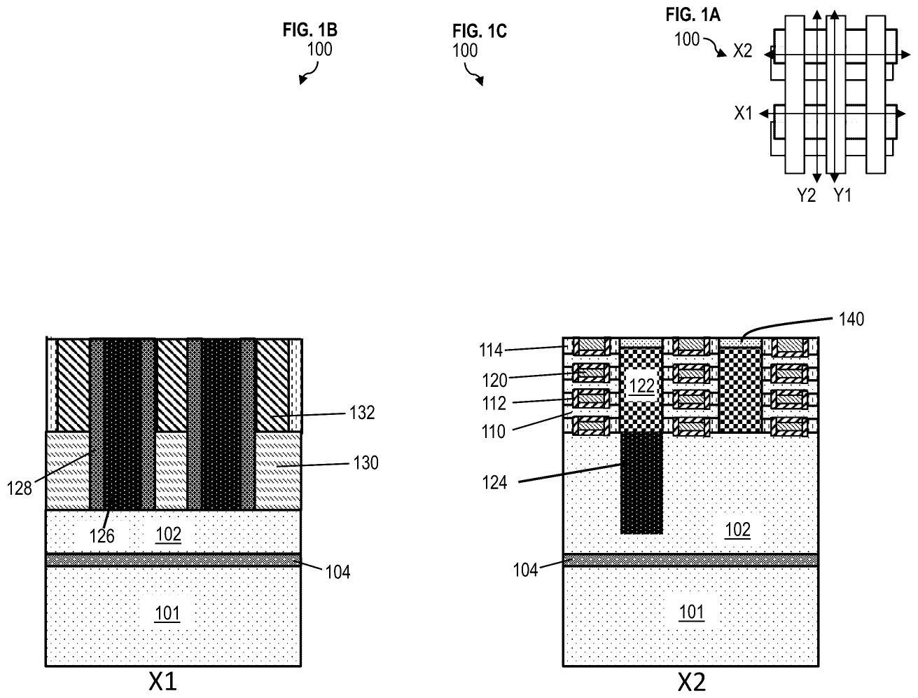

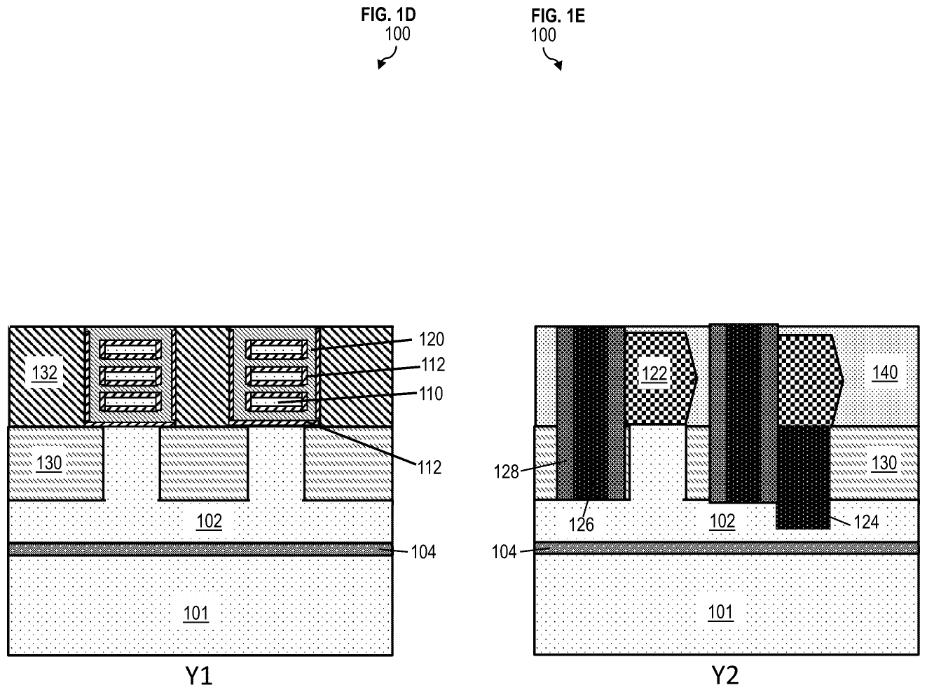

Turning now to a more detailed description of aspects of the present invention, FIG. 1A depicts a top view of a simplified illustration of a portion of an integrated circuit (IC) 100, FIG. 1B depicts a cross-sectional view taken along X1of the IC 100, FIG. 1C depicts a cross-sectional view taken along X2 of the IC 100, FIG. 1D depicts a cross-sectional view taken along Y1 of the IC 100, and FIG. 1E depicts a cross-sectional view taken along Y2 of the IC 100. For ease of understanding, some layers may be omitted from the top view so as not to obscure the figure and to view layers underneath. The top view is intended to provide a simplified illustration and a general orientation, but the top view is not intended to be a complete representation of the device. Future locations of layers may be depicted in the top view to assist the reader. Standard semiconductor fabrication techniques can be utilized to fabricate the IC 100 as understood by one of ordinary skill in the art. Any suitable lithography processes including deposition techniques and etching techniques can be utilized herein.

FIGS. 1A, 1B, 1C, 1D, and 1E depict the IC 100 having a wafer where several known fabrication processes have been performed. A substrate 102 is over on a lower substrate 101 with an (intervening) etch stop layer 104 in between. The substrate 102, lower substrate 101, and semiconductor layers 110 may be formed of silicon or other semiconductor materials. The etch stop layer 104 may be formed of silicon germanium.

Shallow trench isolation (STI) regions 130 are formed in the substrate 102. Material of the STI regions 130 can include low-k dielectric materials, ultra-low-k dielectric materials, etc. A backside contact placeholder 124 is formed in the substrate 102 as sacrificial material. Example materials of the backside contact placeholder 124 may include silicon germanium for etch selectivity in subsequent fabrication processes.

Gate cut dielectric 132 is disposed above the substrate 102 and may include nitride materials such as silicon nitride (SiN). Semiconductor layers 110 are above the substrate 102. A gate is formed around the semiconductor layers 110, and the gate includes a gate material 112 and a gate metal 120. Portions of the gate material 112 line the gate cut dielectric 132, as best seen in FIG. 1D. The semiconductor layers 110 are the channel regions for the bottom transistors. The semiconductor layers 110 are nanosheets separated by inner spacers 114, and the nanosheets can have a thickness of, for example, 5 nanometers. The thickness of a nanosheet can range from about 2-10 nm, and other ranges are possible. The gate material 112 can be a high-k dielectric material. The gate metal 120 is a work function material/material, and different work function materials are utilized for p-type transistors versus n-type transistors. Example materials of the inner spacers 114 can include SiN, SiBCN, SiOCN, SiOC, etc.

Source and drain (source/drain) regions 122 are connected to the semiconductor layer 110. The source/drain regions 122 include epitaxial material that can be doped with n-type or p-type dopants according to whether an n-type or p-type transistor is formed.

Interlayer/intralayer dielectric (ILD) material 140 is formed. The ILD material 140 can include low-k-dielectric materials, ultra-low-k dielectric materials, etc. Backside contact placeholders 126 are formed through the gate cut dielectric 132, ILD material 140, and a portion of the source/drain regions 122. Dielectric spacers 128 can be disposed on the sides of the backside contact placeholders 126. The backside contact placeholders 126 can be formed of the materials utilized to form the backside contact placeholder 124. The dielectric spacers 128 can include SiN, SiBCN, SiOCN, SiOC, etc.

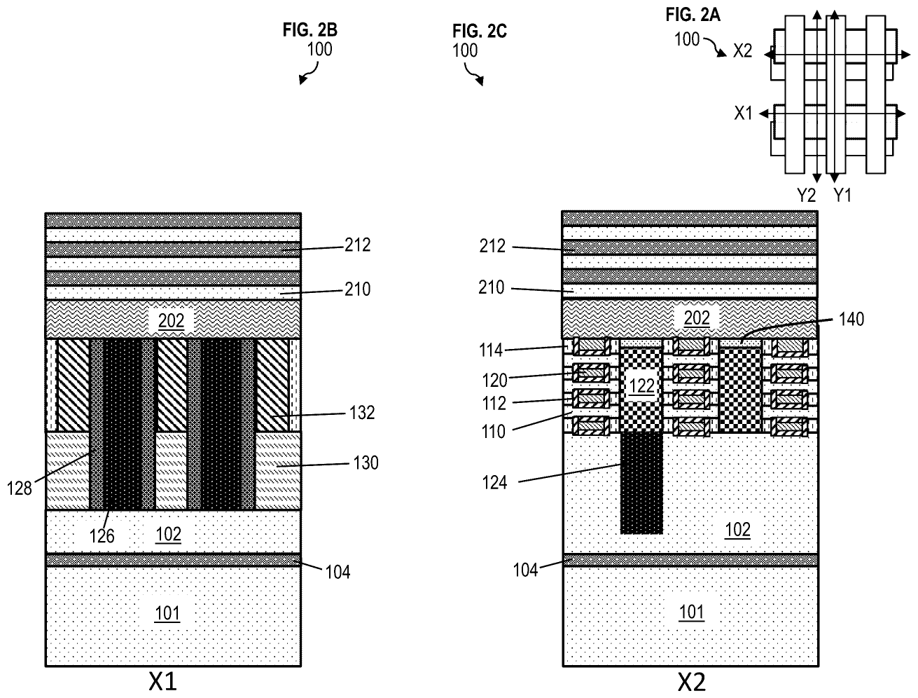

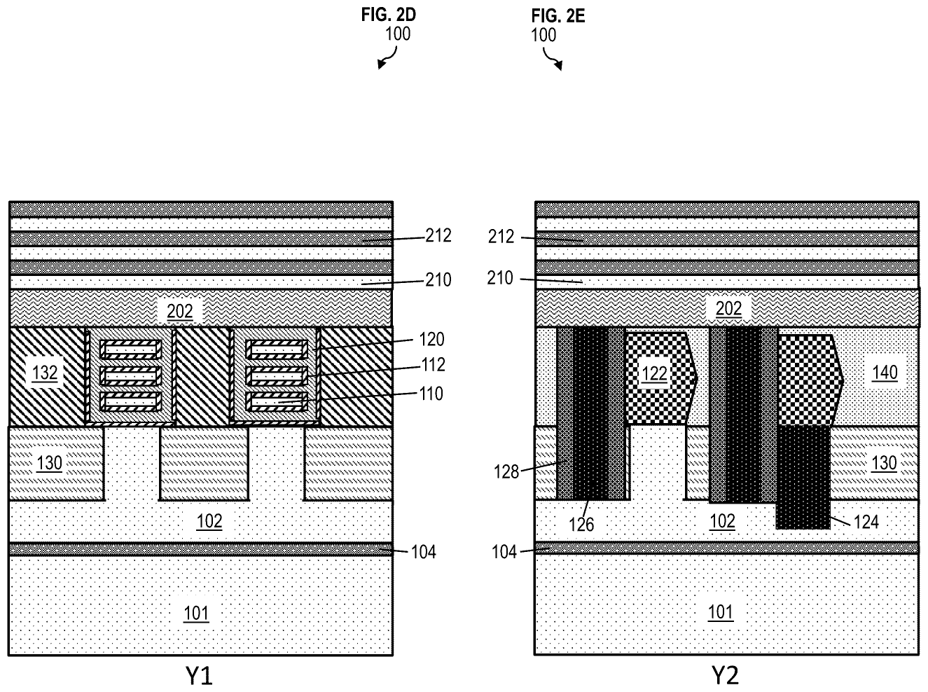

FIGS. 2A, 2B, 2C, 2D, and 2E depict the IC 100 after bonding a wafer with a nanosheet stack to the structure, and then grinding/polishing off the top wafer. A bonding layer 202 can be formed, and the bonding layer 202 may include an oxide material, such as silicon dioxide (SiO₂) or other oxide materials.

A nanosheet stack is formed with alternating layers of semiconductor layers 210 and sacrificial layers 212. The semiconductor layers 210 may include substantially pure silicon and are the channel regions for the upper transistors. The semiconductor layers 210 are nanosheets and can have a thickness ranging from about 2-10 nm, and other ranges are possible. The sacrificial layers 212 are formed of silicon germanium (SiGe).

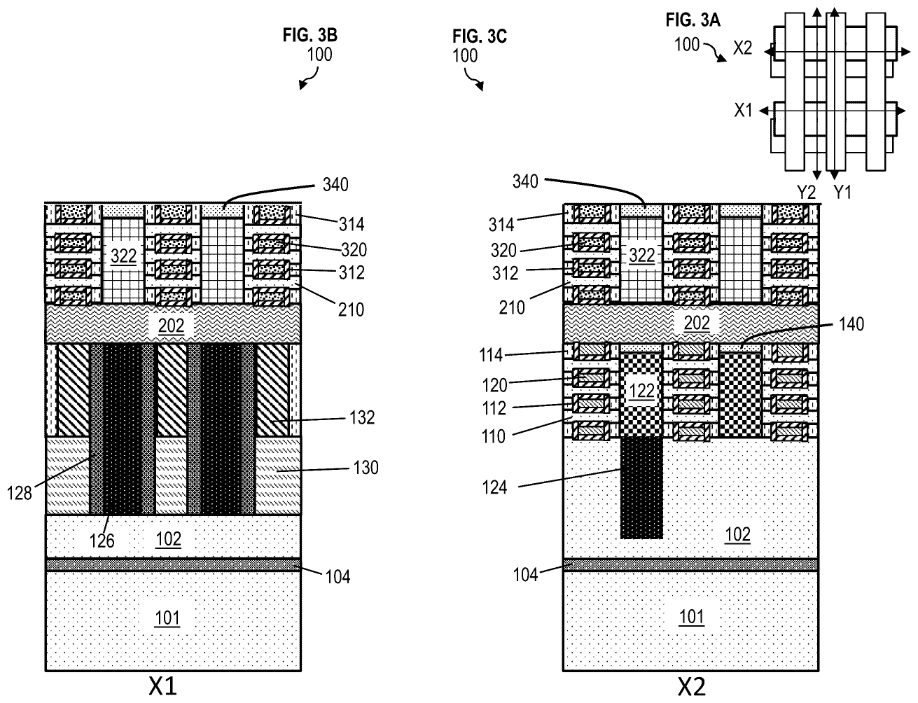

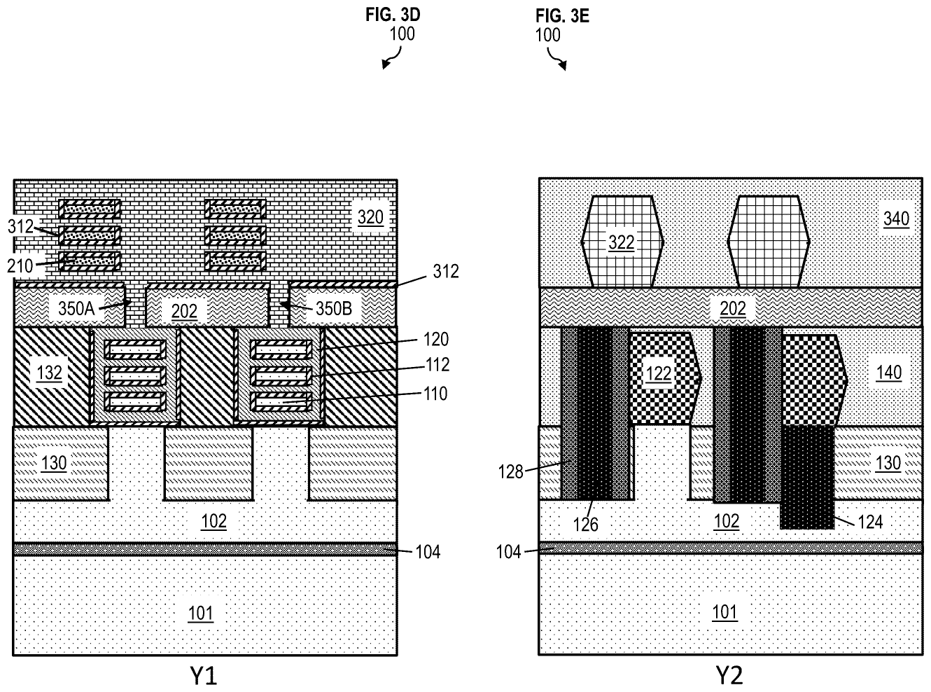

FIGS. 3A, 3B, 3C, 3D, and 3E depict the IC 100 after several fabrication processes. Fabrication processes may include active region patterning, dummy gate formation, spacer formation, upper inner spacer formation, source/drain epitaxial formation, ILD formation, dummy gate removal, channel protection dielectric removal, SiGe removal for sacrificial layers, high-k material deposition for gate material with reliability anneal, shared gate opening into bonding oxide, and work function material/metal deposition of gate metal.

A gate is formed around the semiconductor layers 210, and the gate includes a gate material 312 and a gate metal 320. The semiconductor layers 210 are now the channel regions for the bottom transistors. The semiconductor layers 210 are nanosheets separated by inner spacers 314. The gate material 312 can be a high-k dielectric material. The gate metal 320 is a work function material/material, and different work function materials are utilized for p-type transistors versus n-type transistors. Example materials of the inner spacers 314 can include SiN, SiBCN, SiOCN, SiOC, etc.

Source and drain (source/drain) regions 322 are connected to the semiconductor layers 210. The source/drain regions 322 include epitaxial material that can be doped with n-type or p-type dopants according to whether an n-type or p-type transistor is formed. ILD material 340 is formed, which can include low-k-dielectric materials, ultra-low-k dielectric materials, etc.

Shared gate connections are depicted as a gate connector 350A and gate connector 350B, which connect the gate metal 320 of upper transistors to the gate metal 120 of lower transistors. The gate metal 320 can be a different work function material/metal than the work function material/metal of the gate metal 120. One gate metal can include p-type material while the other gate metal includes n-type material, and vice versa. To form the gate connectors 350A and 350B, etching is performed to breakthrough (upper) gate material 312 and the bonding layer 202 in order to form openings exposing the gate metal 120 below. When depositing the gate metal 320 around the semiconductor layer 210, the material of the gate metal 320 is concurrently deposited in the openings thereby forming the gate connectors 350A and 350B. It will be seen that at least part of the gate metal 320 of one of the gate connectors can be replaced with a different gate metal as discussed herein.

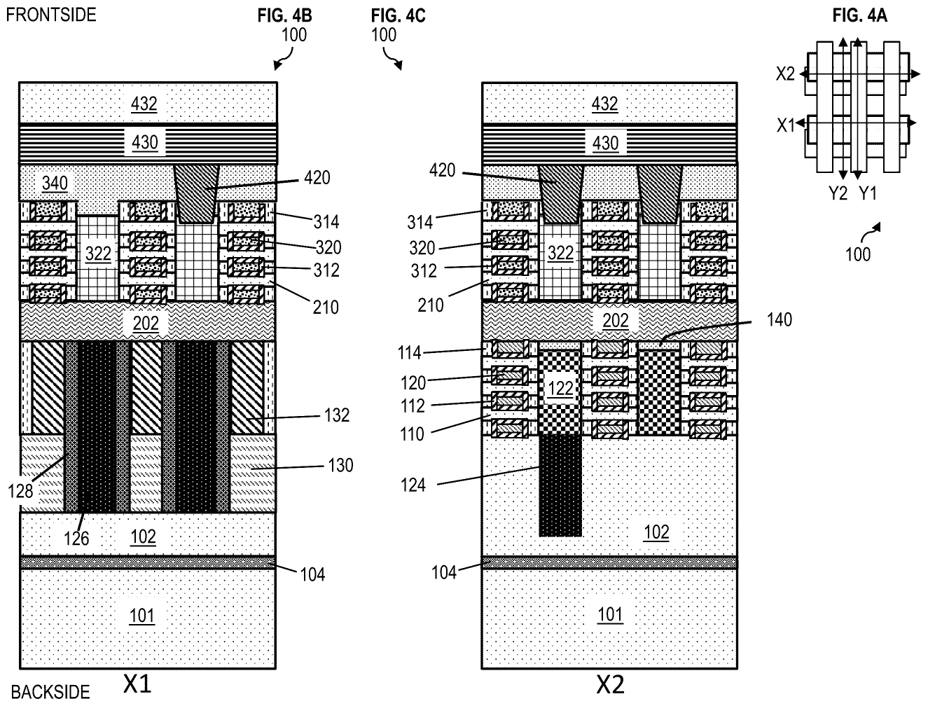

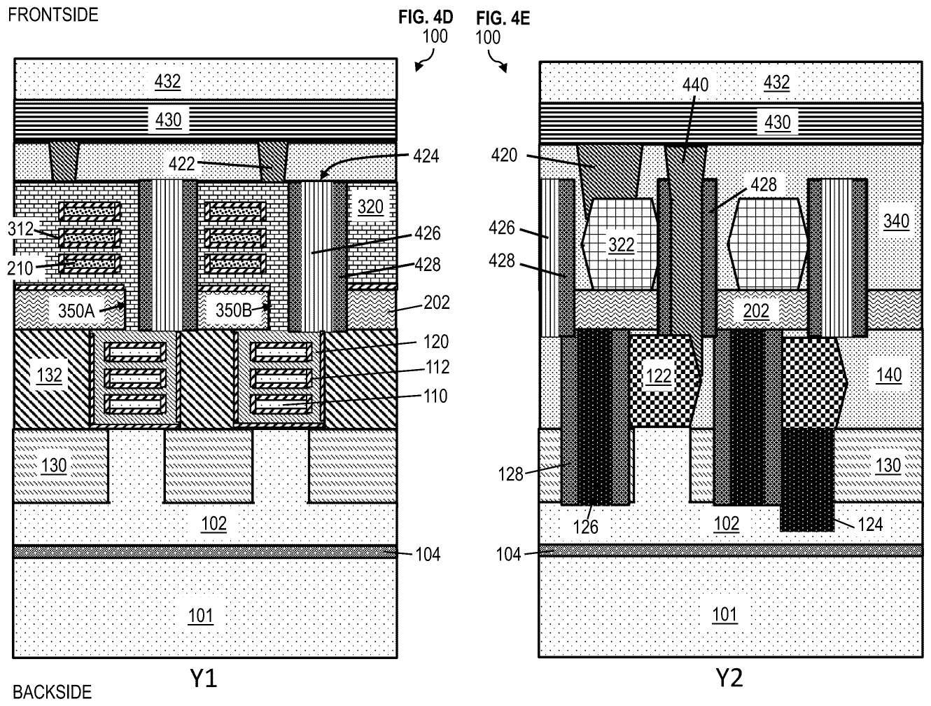

FIGS. 4A, 4B, 4C, 4D, and 4E depict the IC 100 after contact formation and frontside processing. Frontside gate cuts 424 are structures formed in the gate metal 320 and ILD material 340, and the frontside gate cuts 424 include a liner 428 and fill material 426. Example materials of the fill material 426 may include oxide materials. The liner 428 can include nitride materials such as SiN, SiBCN, SiOCN, etc. Materials of the liner 428 and the fill material 426 are selected to have etch selectivity with respect to each other.

Additional material of the ILD material 340 is deposited, and frontside S/D contacts 420, frontside gate contacts 422, and frontside S/D contact 440 are formed. In one or more embodiments, part of the frontside gate cut 424 is patterned to define an opening for the frontside S/D contact 440 by selectively etching away fill material 426 in the opening while retaining the liner 428. The opening is filled with conductive material to form the frontside S/D contact 440 that extends down to the (bottom) source/drain regions 122 of the lower transistors. The contacts may be referred to as metal contacts. Example conductive materials of the frontside S/D contacts 440 can include tungsten, titanium, titanium nitride, aluminum, nickel, chromium, copper, gold, etc., along with various combinations and liners.

BEOL processing can be performed to form a frontside interconnect layer 430, and a carrier wafer 432 is bonded on the frontside interconnect layer 430 in preparation for wafer flip.

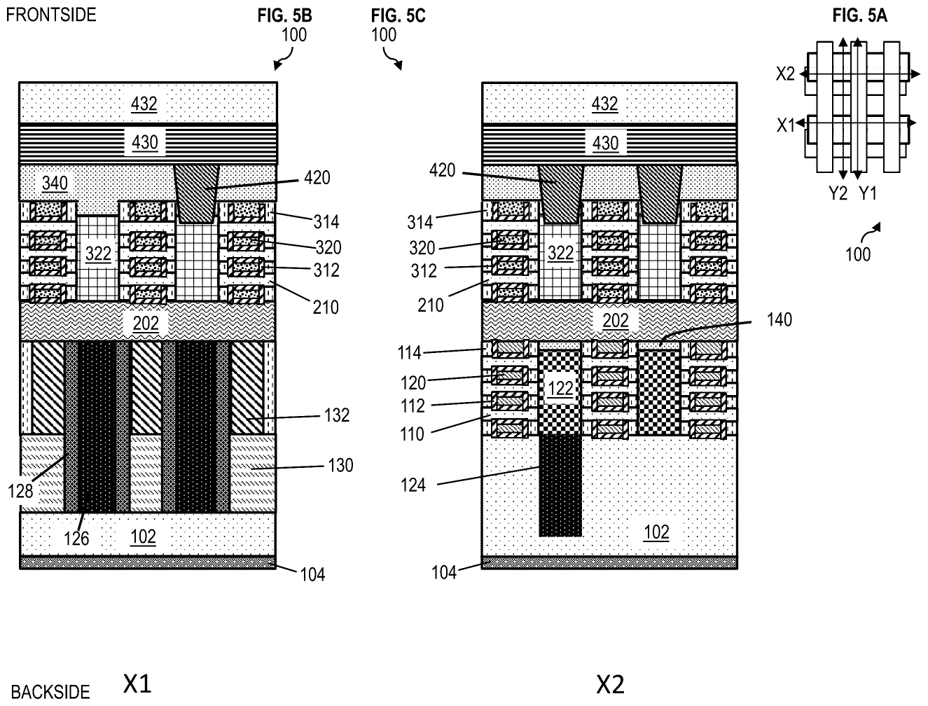

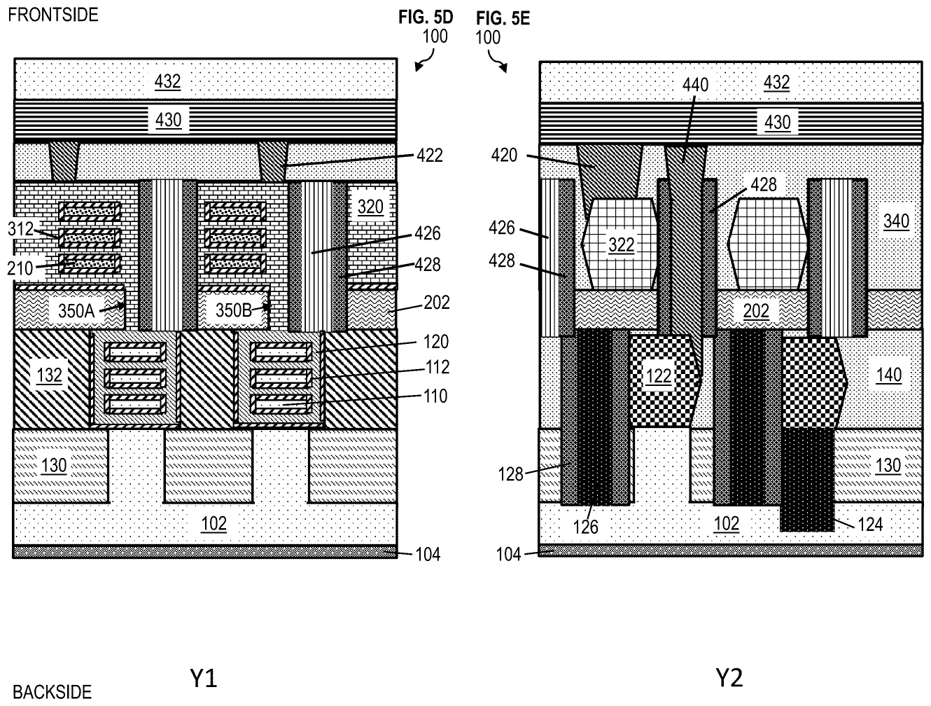

FIGS. 5A, 5B, 5C, 5D, and 5E depict the IC 100 after wafer flip and lower substrate removal. The wafer is flipped, and processing continues on the backside of the semiconductor structure. For consistency and to assist the reader, the wafer is not illustrated as being flipped in the figures, although it is understood that wafer is flipped with fabrication processing performed on the backside.

The lower substrate 101 is removed to expose the etch stop layer 104. Etching and/or chemical mechanical polishing/planarization (CMP) may be utilized to remove the lower substrate 101.

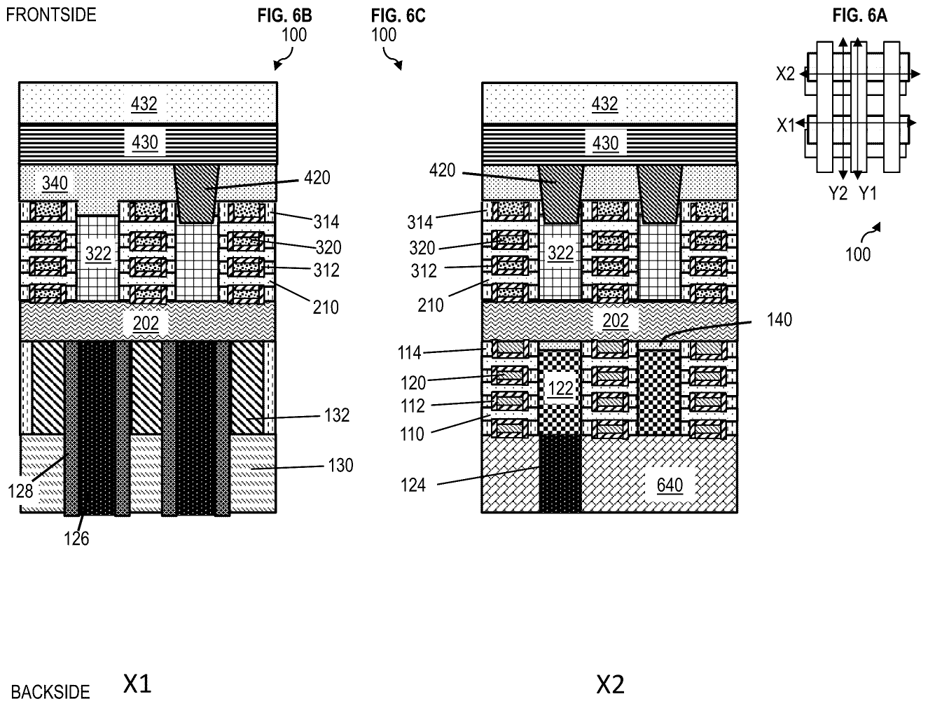

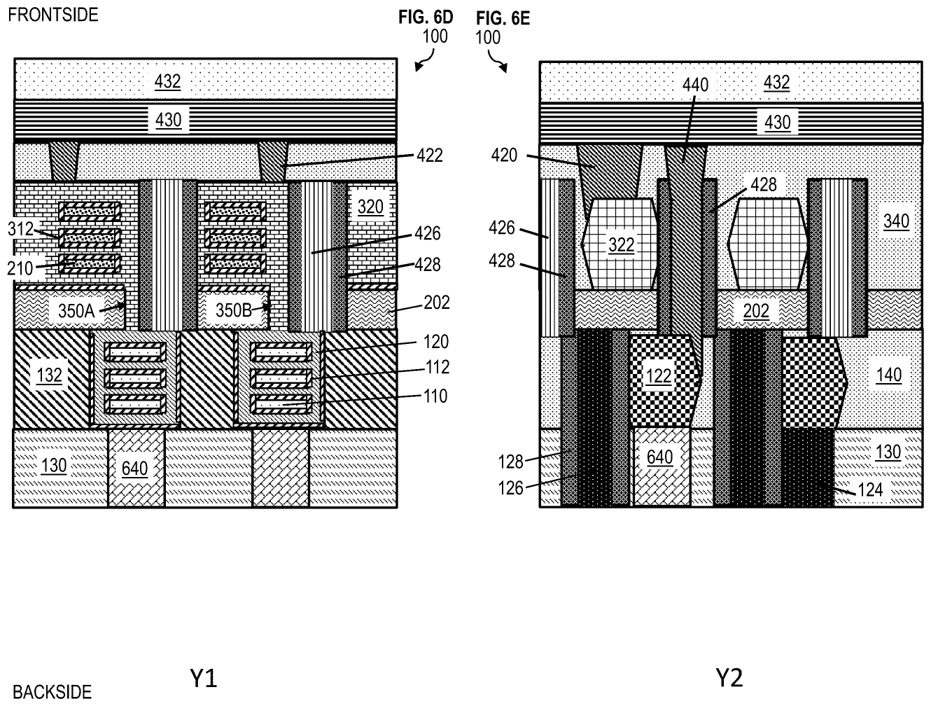

FIGS. 6A, 6B, 6C, 6D, and 6E depict the IC 100 after removing the silicon germanium layer and the remaining silicon substrate. The etch stop layer 104 is removed, and the substrate 102 is removed. Backside ILD material 640 is deposited to fill the cavities left from removing the substrate 102, and CMP is performed.

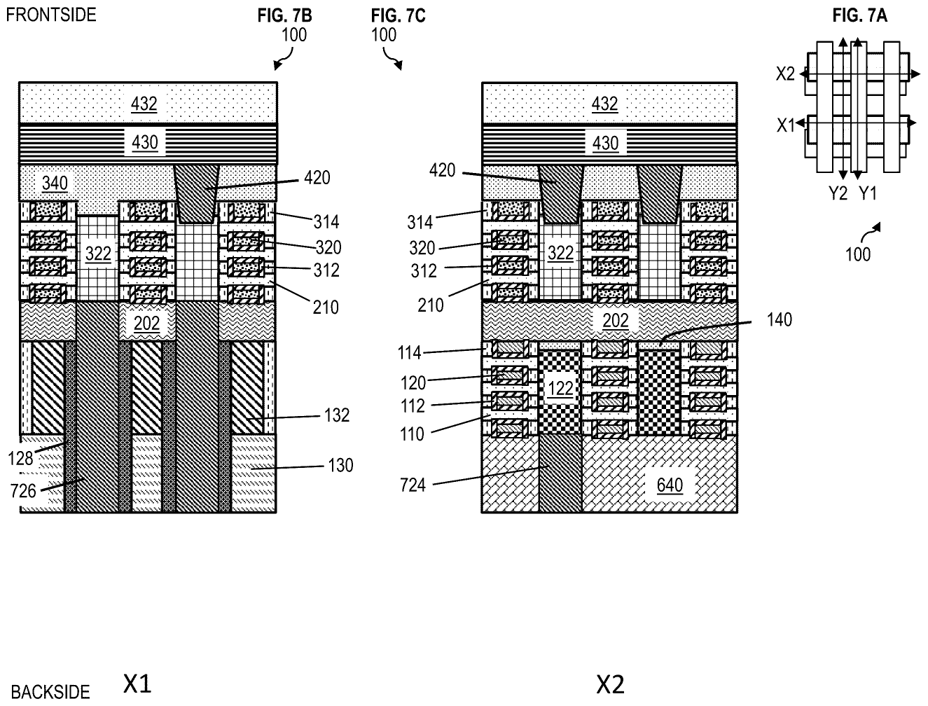

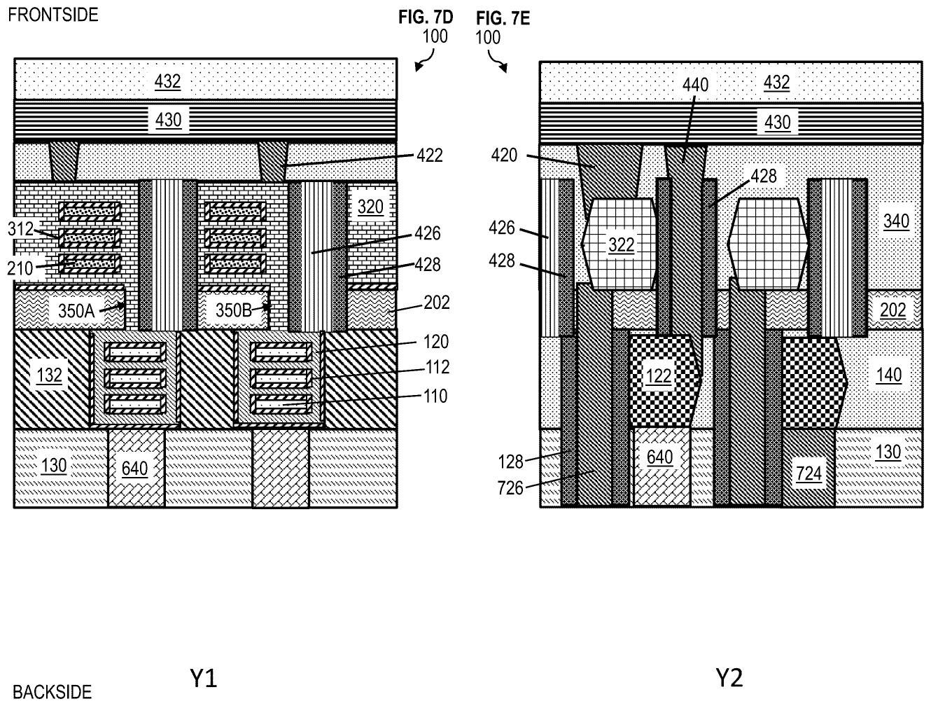

FIGS. 7A, 7B, 7C, 7D, and 7E depict the IC 100 after silicon germanium removal and backside contact formation. The backside contact placeholders 124 and 126 are selectively etched leaving cavities, and the cavities are filled with conductive material to form backside S/D contacts 724 and 726. The backside S/D contacts 724 and 726 can include materials utilized to form frontside S/D contacts 420 and 440 and frontside gate contacts 422.

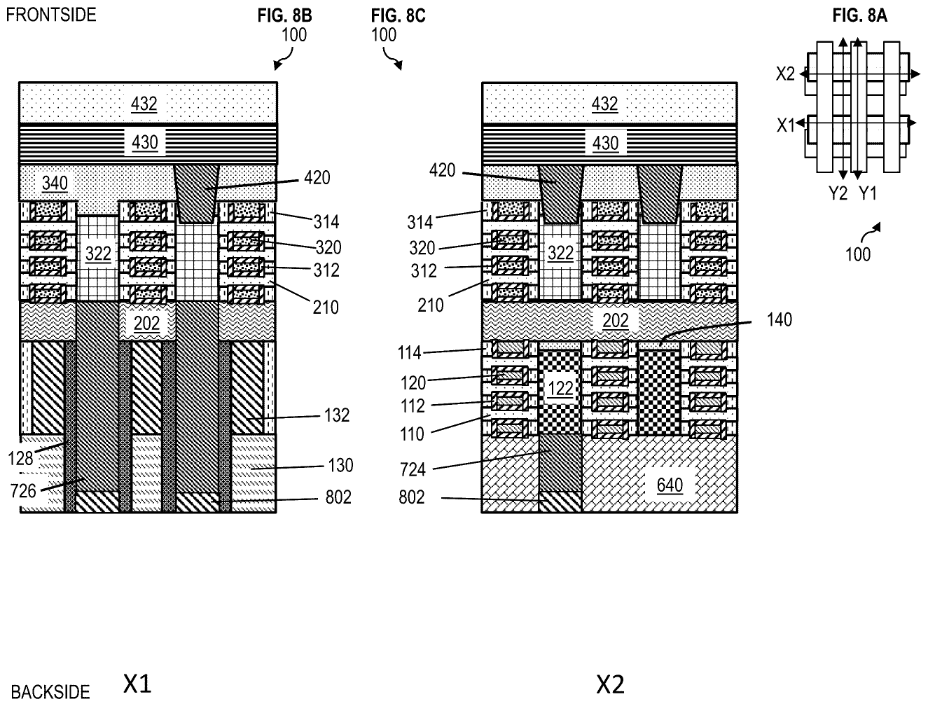

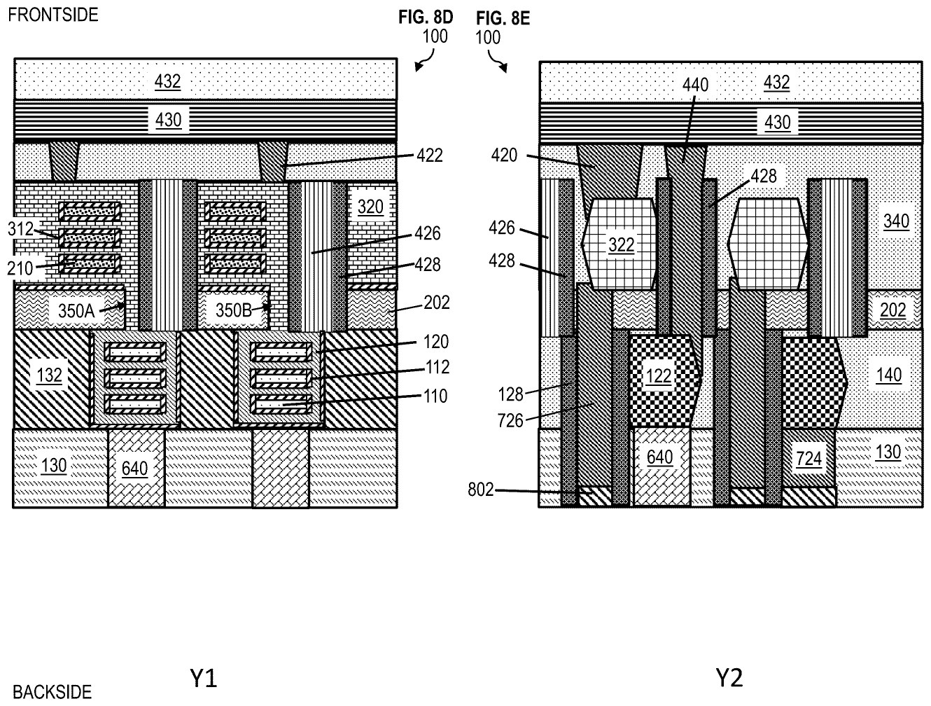

FIGS. 8A, 8B, 8C, 8D, and 8E depict the IC 100 after backside contact recess and protective cap formation. Using lithography, etching is performed to recess a portion of the backside S/D contacts 724 and 726. Deposition is performed to form caps 802 on the recessed portions of the backside S/D contacts 724 and 726. The caps 802 may include nitride materials including silicon nitride, etc.

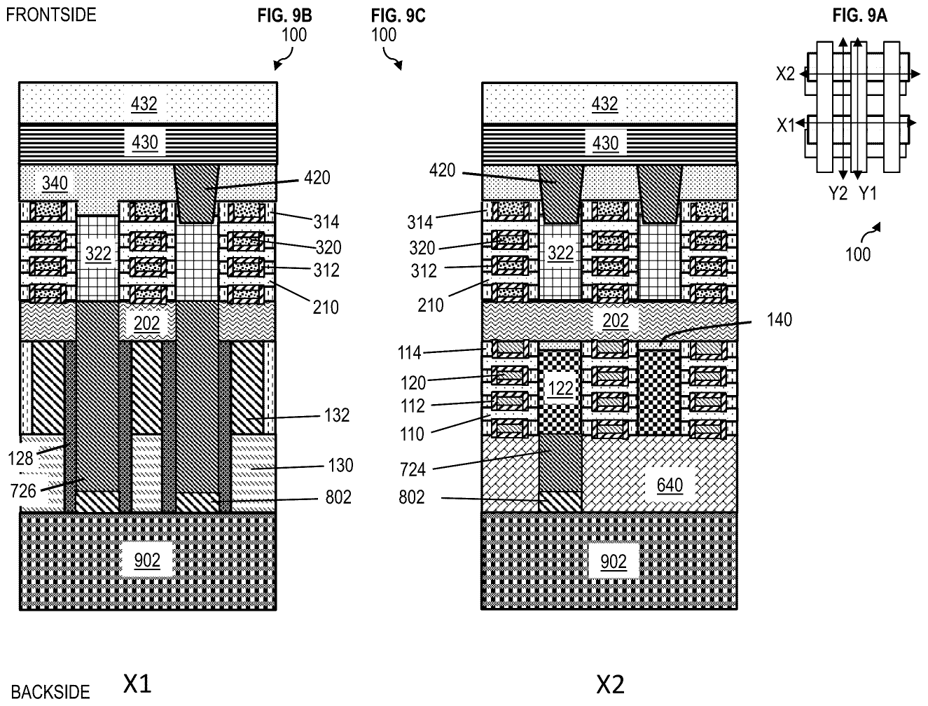

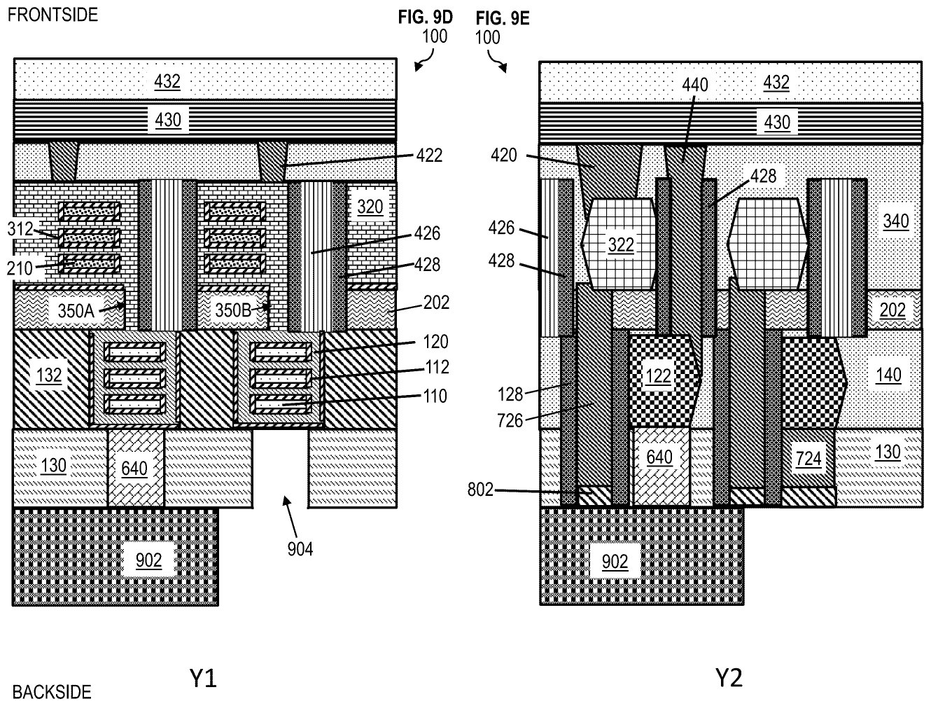

FIGS. 9A, 9B, 9C, 9D, and 9E depict the IC 100 after backside ILD opening for super-low threshold voltage device. An organic planarization layer (OPL) 902 is formed and patterned such that a portion of the backside ILD material 640 is exposed. Using the (patterned) OPL 902, etching is performed to selectively remove the exposed portion of the backside ILD material 640 resulting in cavity 904, without removing the STI region 130. The materials of the backside ILD material 640 and STI region 130 are chosen to provide etch selectivity. For example, the STI region 130 typically has a liner (not separately shown) that has etch selectivity to the backside ILD material 640. The etching exposes part of the gate material 112 below the gate metal 120, which is in preparation for breakthrough of the gate material 112.

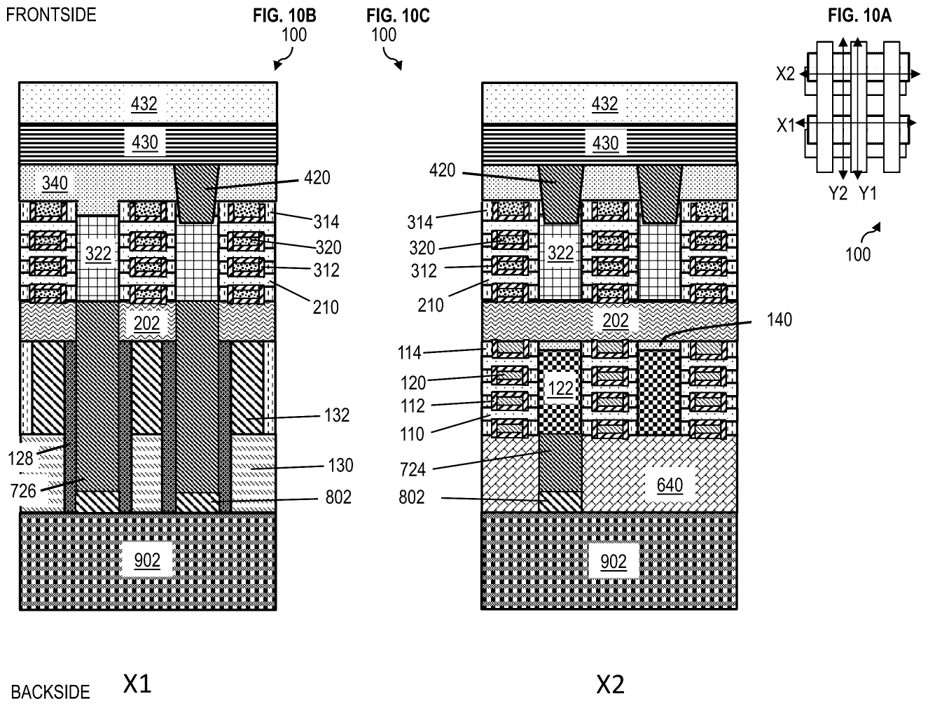

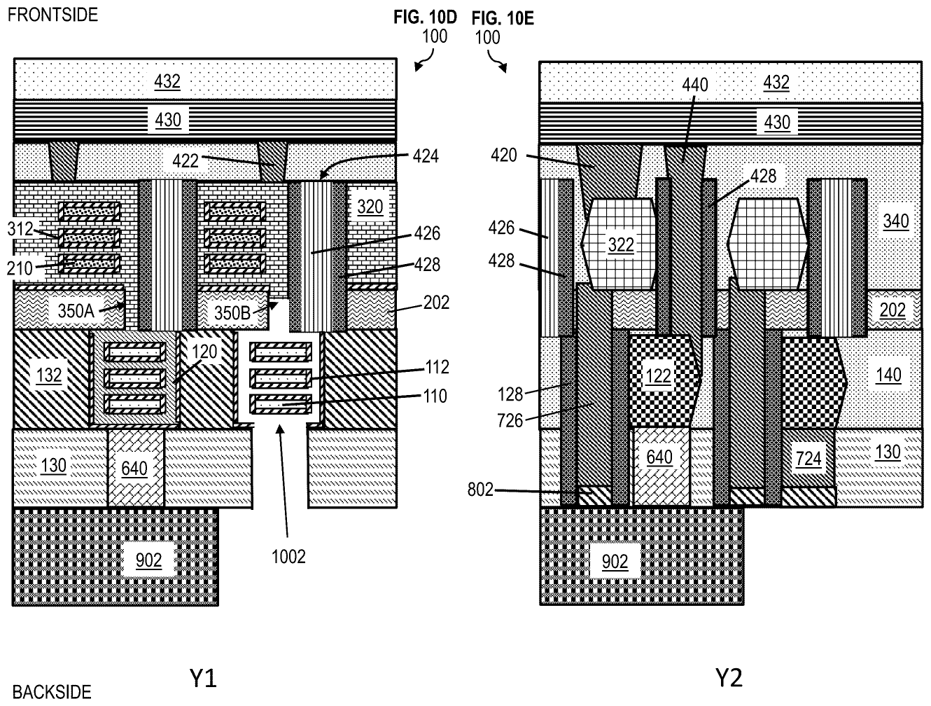

FIGS. 10A, 10B, 10C, 10D, and 10E depict the IC 100 after gate material breakthrough and work function material removal. Etching is performed to remove a portion of the gate material 112 below the gate metal 120, such that the gate metal 120 is exposed. Etching continues to remove the (exposed) gate metal 120 and a portion of the gate metal 320 in the gate connector 350B, resulting in cavity 1002 around the semiconductor layers 110 of one of the lower transistors. In one or more embodiments, less material of the gate metal 320 forming the gate connector 350B is removed. In one or more embodiments, the gate metal 320 forming the gate connecter 350B can be completely removed.

Any suitable etching can be performed to etch the gate material 112, the gate metal 120, and the gate metal 320. A wet or dry etch may be utilized. For example, a wet etch can be utilized to remove the gate material (high-k) 112, the gate metal 120, and the gate metal 320 without removing the STI region 130 and (nitride) caps 802. In one or more embodiments, the STI region 130 has a nitride liner (not separately shown) so that the etch chemistry etches the backside ILD material 640 (as noted above) and the bottom portion of the gate material 112, for example, using a buffered hydrofluoric (HF) acid. The frontside gate cut 424 includes oxide and nitride, and the etch chemistry to etch the gate metal 120 and the gate metal 320 excludes etching the frontside gate cut 424; an example etch chemistry is Standard Clean 1 (SC1), which is a process that uses a solution of ammonium hydroxide and hydrogen peroxide.

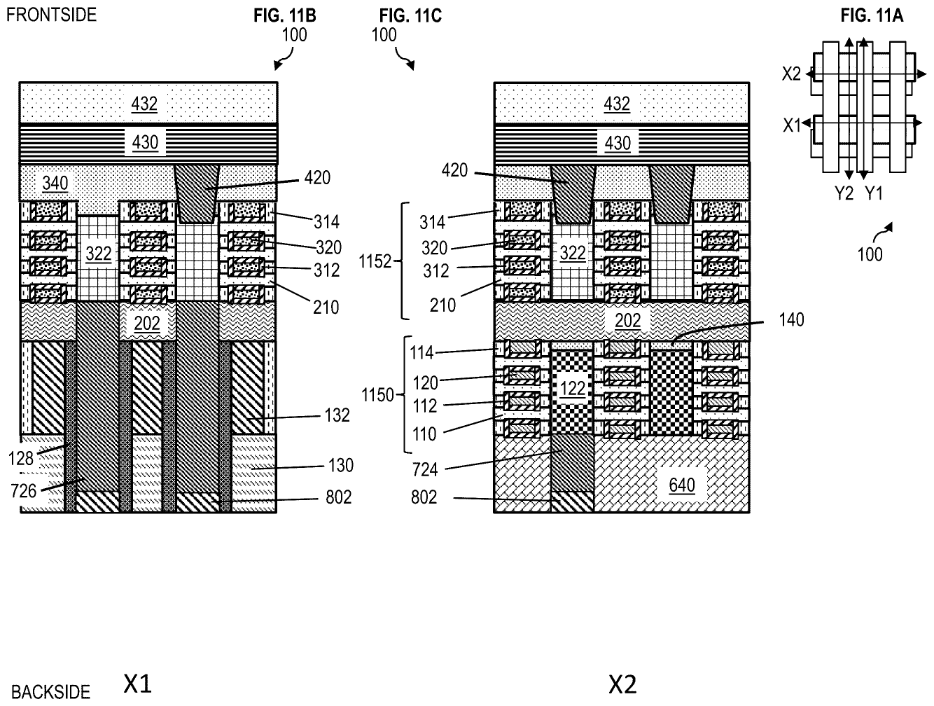

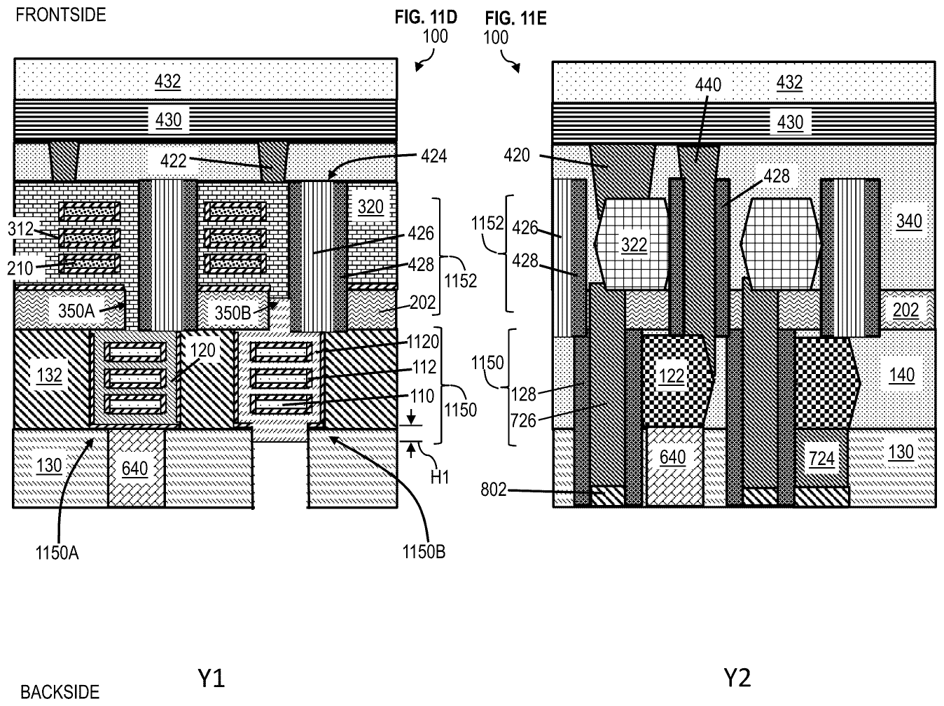

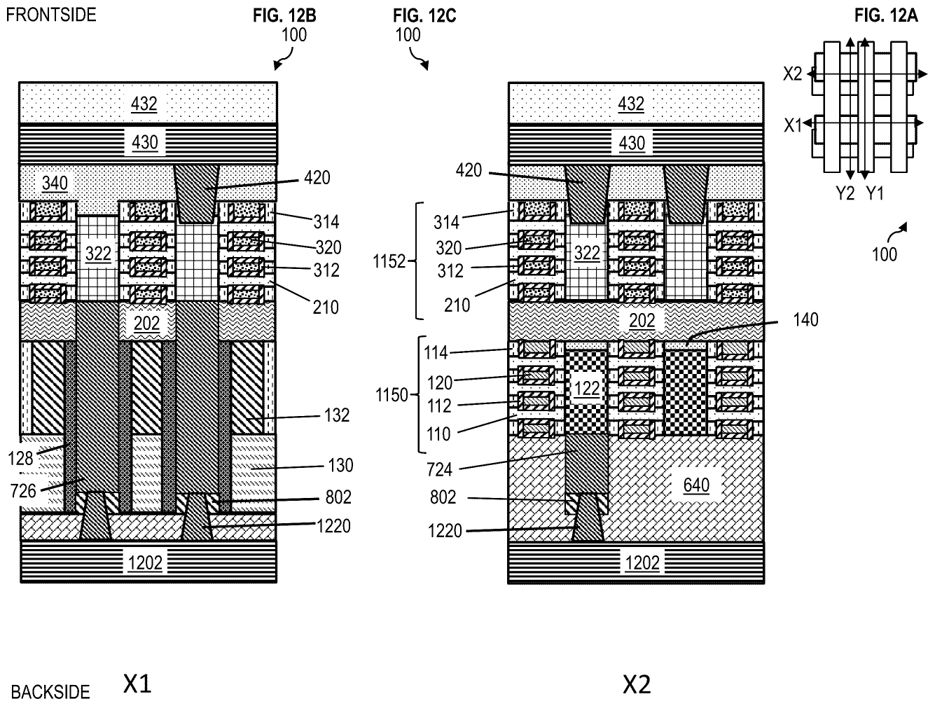

FIGS. 11A, 11B, 11C, 11D, and 11E depict the IC 100 after deposition of new work function material/metal and recess. The cavity 1002 is filed with gate metal 1120. A portion of the gate connector 350B is filled with the gate metal 1120. In one or more embodiments, the entirety of the gate connector 350B can be filled with gate metal 1120.

As can be seen, lower transistors 1150 are below upper transistors 1152. The gate metal 320 can be the same materials in the upper transistors 1152. However, the gate metals 120 and 1120 are different materials in the lower transistors 1150. For example, the gate metal 120 of lower transistor 1150A is different from the gate metal 1120 of lower transistor 1150B. The gate metals 120, 320, and 1120 can each be different work function materials/metals to achieve their desired threshold voltages.

The work function material/metal of the gate metal 1120 may be thermal sensitive, and accordingly, the gate metal 1120 is formed subsequent to the fabrication processes including thermal anneal processes for the upper transistors 1152. The (later formed) gate metal 1120 is not subject to the thermal annealing performed during the formation of the upper transistors 1152. Examples of thermal sensitive work function materials/metals for the gate metal 1120 can include materials for a super-low threshold voltage (SLVT) PFET, and work function materials of the SVLT PEFT can include titanium nitride, molybdenum nitride, tantalum nitride, tungsten nitride, tungsten, ruthenium, platinum, rhenium, iridium, and/or palladium. In one or more embodiments, the gate metal 1120 of the lower transistor 1150B is utilized to form a super-low threshold voltage transistor, but thermal annealing can cause the threshold voltage of the lower transistor 1150B to increase. Accordingly, the gate metal 1120 is deposited after thermal annealing has been completed, particularly after forming the upper transistors 1152. In one or more embodiments, the lower transistor 1150A has a higher threshold voltage than the lower transistor 1150B. The gate metal 1120 of the lower transistor 1150B has a greater depth/height/distance H1 below the bottom surface of the gate metal 120 of the lower transistor 1150A. For example, the gate metal 1120 extends a distance H1 below the bottom surface of the (adjacent) gate metal 120.

In one or more embodiments, the lower transistor 1150A, the lower transistor 1150B, and the upper transistors 1152 can each have different threshold voltages, resulting in, for example, three different threshold voltages for stacked transistors. The lower transistor 1150B can have the super-low threshold voltage, the lower transistor 1150A can have a medium threshold voltage, and the upper transistors 1152 can have a high threshold voltage, where the super-low threshold voltage is less than the medium threshold voltage that is less than high threshold voltage. In one or more embodiments, the lower transistor 1150B can have the super-low threshold voltage, the lower transistor 1150A can have a high threshold voltage, and the upper transistors 1152 can have a medium threshold voltage. The upper transistors 1152 and the lower transistors 1150 can have complimentary polarities. For example, the upper transistors 1152 can be p-type transistors (PFETs) while the lower transistors 1150 are n-type transistors (NFETs), or vice versa.

The upper transistors 1152 are stacked on lower transistors 1150A and 1150B. For example, first stacked transistors can include one of the upper transistors 1152 over lower transistor 1150A, while second stacked transistors can include another one of the upper transistors 1152 over the lower transistor 1150B.

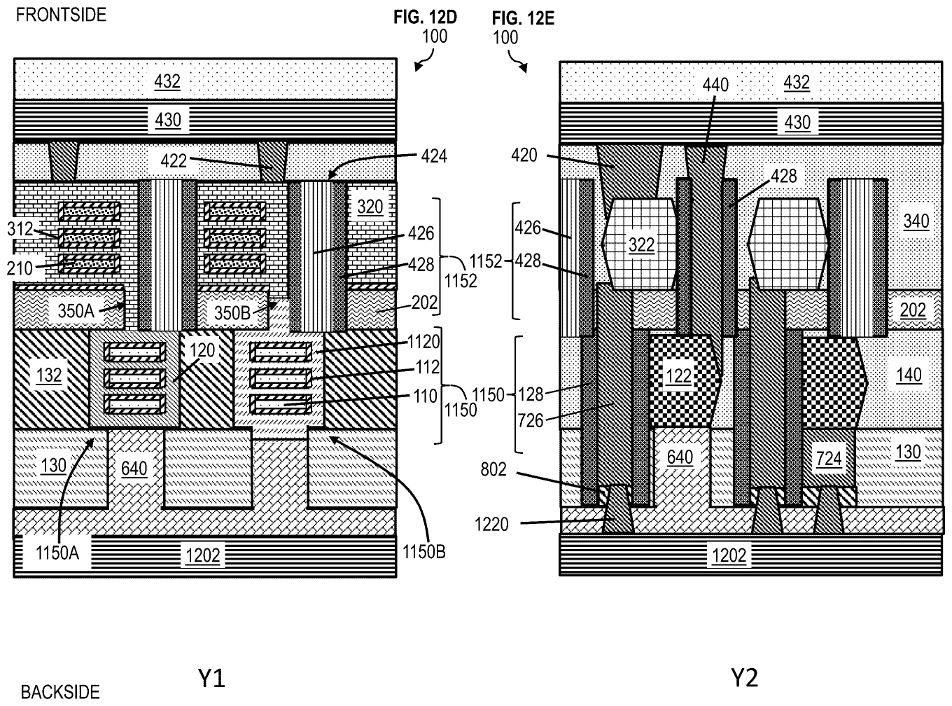

FIGS. 12A, 12B, 12C, 12D, and 12E depict the IC 100 after backside interconnect formation. Additional material of the backside ILD material 640 is formed, and backside contact vias 1220 are formed. The backside contact vias 1220 can include materials utilized to form frontside S/D contacts 420 and 440 and frontside gate contacts 422. A backside interconnect layer 1202 is formed on the backside contact vias 1220.

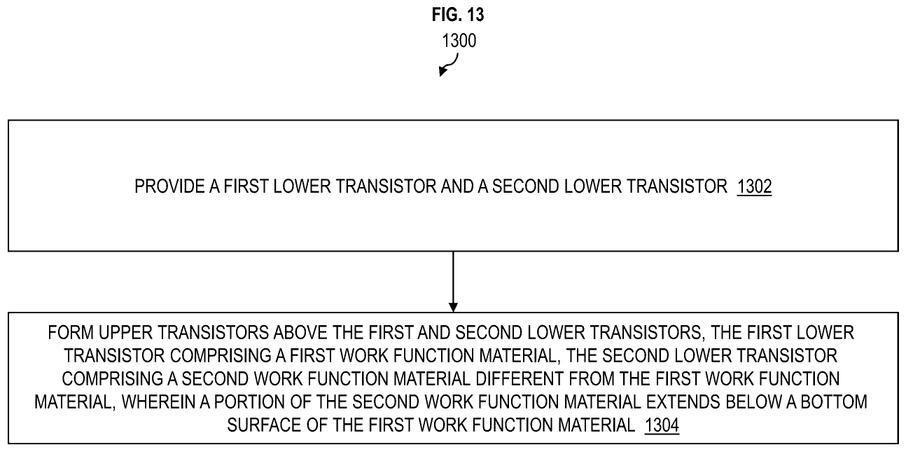

FIG. 13 is a flowchart of a method 1300 for forming an IC 100 with work function material/metal fill from the backside according to one or more embodiments. Reference can be made to any figures discussed herein. At block 1302, the method 1300 includes providing a first lower transistor (e.g., lower transistor 1150A) and a second lower transistor (e.g., lower transistor 1150B). At block 1304, the method 1300 includes forming upper transistors (e.g., upper transistors 1152) above the first and second lower transistors, the first lower transistor comprising a first work function material (e.g., gate metal 120), the second lower transistor comprising a second work function material (e.g., gate metal 1120) different from the first work function material. A portion of the second work function material (e.g., gate metal 1120) extends (e.g., a distance H1) below a bottom surface of the first work function material (e.g., gate metal 120).

The upper transistors 1152 comprise a third work function material (e.g., gate metal 320) different from the second work function material (e.g., gate metal 1120). A gate connector 350B connects one of the upper transistors 1152 to the second lower transistor (e.g., lower transistor 1150B), a part of the gate connector 350B comprising the second work function material (e.g., gate metal 1120). A gate connector 350B connects one of the upper transistors 1152 to the second lower transistor (e.g., lower transistor 1150B), the gate connector comprising the second work function material (e.g., gate metal 1120) and a third work function material (e.g., gate metal 320) of the one of the upper transistors.

The second lower transistor (e.g., lower transistor 1150B) comprises a gate dielectric material (e.g., gate material 112), an opening (e.g., the opening of cavity 1002) being in the gate dielectric material (e.g., gate material 112) of the second lower transistor. The second work function material (e.g., gate metal 1120) is disposed in the opening (e.g., the opening of cavity 1002) of the second lower transistor (e.g., lower transistor 1150B). The second work function material extends (e.g., a distance H1) through the opening of the second lower transistor (e.g., lower transistor 1150B).

Further, the second work function material (e.g., gate metal 1120) is filled from a backside of the semiconductor structure (e.g., IC 100), as depicted in FIG. 11D. The second lower transistor (e.g., 1150B) comprises a super-low threshold voltage, the first lower transistor (e.g., 1150A) comprises a medium threshold voltage, and the upper transistors 1152 comprise a high threshold voltage.

As discussed herein, gate material is formed around the semiconductor layers. The gate material includes high-k material and work function material generally referred to as a high-k metal gate (HKMG). Techniques for forming HKMG in gate openings are well-known in the art and, thus, the details have been omitted in order to allow the reader to focus on the salient aspects of the disclosed methods. However, it should be understood that such HKMG will generally include formation of one or more gate dielectric layers (e.g., an inter-layer (IL) oxide and a high-k gate dielectric layer), which are deposited so as to line the gate openings, and formation of one or more metal layers, which are deposited onto the gate dielectric layer(s) so as to fill the gate openings. The materials and thicknesses of the dielectric and metal layers used for the HKMG can be preselected to achieve desired work functions given the conductivity type of the FET. To avoid clutter in the drawings and to allow the reader to focus on the salient aspects of the disclosed methods, the different layers within the HKMG stack are not illustrated. For explanation purposes, a high-k gate dielectric layer can be, for example, a dielectric material with a dielectric constant that is greater than the dielectric constant of silicon dioxide (i.e., greater than 3.9). Exemplary high-k dielectric materials include, but are not limited to, hafnium (Hf)-based dielectrics (e.g., hafnium oxide, hafnium silicon oxide, hafnium silicon oxynitride, hafnium aluminum oxide, etc.) or other suitable high-k dielectrics (e.g., aluminum oxide, tantalum oxide, zirconium oxide, etc.). Optionally, the metal layer(s) can include a work function metal that is immediately adjacent to the gate dielectric layer and that is preselected in order to achieve an optimal gate conductor work function given the conductivity type of the nanosheet-FET. For example, the optimal gate conductor work function for the PFETs can be, for example, between about 4.9 eV and about 5.2 eV. Exemplary metals (and metal alloys) having a work function within or close to this range include, but are not limited to, ruthenium, palladium, platinum, cobalt, and nickel, as well as metal oxides (aluminum carbon oxide, aluminum titanium carbon oxide, etc.) and metal nitrides (e.g., titanium nitride, titanium silicon nitride, tantalum silicon nitride, titanium aluminum nitride, tantalum aluminum nitride, etc.). The optimal gate conductor work function for NFETs can be, for example, between 3.9 eV and about 4.2 eV. Exemplary metals (and metal alloys) having a work function within or close to this range include, but are not limited to, hafnium, zirconium, titanium, tantalum, aluminum, and alloys thereof, such as, hafnium carbide, zirconium carbide, titanium carbide, tantalum carbide, and aluminum carbide. The metal layer(s) can further include a fill metal or fill metal alloy, such as tungsten, a tungsten alloy (e.g., tungsten silicide or titanium tungsten), cobalt, aluminum, or any other suitable fill metal or fill metal.

Although not shown in detail, contact formation and ILD formation are performed. As such, ILD material can be deposited, source/drain contact openings are patterned by conventional lithography, and then metal is deposited to fill the cavities thereby forming metal contacts. A portion of the metal contacts may include silicide, resulting from the interface of the metal material and semiconductor material. The metal contacts are source/drain contacts that are respectively connected to epitaxial source/drain regions.

The ILD material can be SiO₂, SiN, a low-k dielectric material or an ultra-low-k dielectric material. Low-k dielectric materials may generally include dielectric materials having a k value of about 3.9 or less. The ultra-low-k dielectric material generally includes dielectric materials having a k value less than 2.5. Unless otherwise noted, all k values mentioned in the present application are measured relative to a vacuum. Exemplary ultra-low-k dielectric materials generally include porous materials such as porous organic silicate glasses, porous polyamide nanofoams, silica xerogels, porous hydrogen silsequioxane (HSQ), porous methylsilsesquioxane (MSQ), porous inorganic materials, porous CVD materials, porous organic materials, or combinations thereof. The ultra-low-k dielectric material can be produced using a templated process or a sol-gel process as is generally known in the art. In the templated process, the precursor typically contains a composite of thermally labile and stable materials. After film deposition, the thermally labile materials can be removed by thermal heating, leaving pores in the dielectric film. In the sol gel process, the porous low-k dielectric films can be formed by hydrolysis and polycondensation of an alkoxide(s) such as tetraetehoxysilane (TEOS).

Various embodiments of the present invention are described herein with reference to the related drawings. Alternative embodiments can be devised without departing from the scope of this invention. Although various connections and positional relationships (e.g., over, below, adjacent, etc.) are set forth between elements in the following description and in the drawings, persons skilled in the art will recognize that many of the positional relationships described herein are orientation-independent when the described functionality is maintained even though the orientation is changed. These connections and/or positional relationships, unless specified otherwise, can be direct or indirect, and the present invention is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The phrase “selective to,” such as, for example, “a first element selective to a second element,” means that the first element can be etched and the second element can act as an etch stop.

As used herein, “p-type” refers to the addition of impurities to an intrinsic semiconductor that creates deficiencies of valence electrons. In a silicon-containing substrate, examples of p-type dopants, i.e., impurities, include but are not limited to: boron, aluminum, gallium and indium.

As used herein, “n-type” refers to the addition of impurities that contributes free electrons to an intrinsic semiconductor. In a silicon containing substrate examples of n-type dopants, i.e., impurities, include but are not limited to antimony, arsenic and phosphorous.

As previously noted herein, for the sake of brevity, conventional techniques related to semiconductor device and integrated circuit (IC) fabrication may or may not be described in detail herein. By way of background, however, a more general description of the semiconductor device fabrication processes that can be utilized in implementing one or more embodiments of the present invention will now be provided. Although specific fabrication operations used in implementing one or more embodiments of the present invention can be individually known, the described combination of operations and/or resulting structures of the present invention are unique. Thus, the unique combination of the operations described in connection with the fabrication of a semiconductor device according to the present invention utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device.

As noted above, atomic layer etching processes can be used in the present invention for via residue removal, such as can be caused by via misalignment. The atomic layer etch process provide precise etching of metals using a plasma-based approach or an electrochemical approach. The atomic layer etching processes are generally defined by two well-defined, sequential, self-limiting reaction steps that can be independently controlled. The process generally includes passivation followed selective removal of the passivation layer and can be used to remove thin metal layers on the order of nanometers. An exemplary plasma-based approach generally includes a two-step process that generally includes exposing a metal such a copper to chlorine and hydrogen plasmas at low temperature (below 20° C.). This process generates a volatile etch product that minimizes surface contamination. In another example, cyclic exposure to an oxidant and hexafluoroacetylacetone (Hhfac) at an elevated temperature such as at 275° C. can be used to selectively etch a metal such as copper. An exemplary electrochemical approach also can include two steps. A first step includes surface-limited sulfidization of the metal such as copper to form a metal sulfide, e.g., Cu₂S, followed by selective wet etching of the metal sulfide, e.g., etching of Cu₂S in HCl. Atomic layer etching is relatively recent technology and optimization for a specific metal is well within the skill of those in the art. The reactions at the surface provide high selectivity and minimal or no attack of exposed dielectric surfaces.

Semiconductor lithography is the formation of three-dimensional relief images or patterns on the semiconductor substrate for subsequent transfer of the pattern to the substrate. In semiconductor lithography, the patterns are formed by a light sensitive polymer called a photoresist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

The photoresist can be formed using conventional deposition techniques such chemical vapor deposition, plasma vapor deposition, sputtering, dip coating, spin-on coating, brushing, spraying and other like deposition techniques can be employed. Following formation of the photoresist, the photoresist is exposed to a desired pattern of radiation such as X-ray radiation, extreme ultraviolet (EUV) radiation, electron beam radiation or the like. Next, the exposed photoresist is developed utilizing a conventional resist development process.

After the development step, the etching step can be performed to transfer the pattern from the patterned photoresist into the interlayer dielectric. The etching step used in forming the at least one opening can include a dry etching process (including, for example, reactive ion etching, ion beam etching, plasma etching or laser ablation), a wet chemical etching process or any combination thereof.

For the sake of brevity, conventional techniques related to making and using aspects of the invention may or may not be described in detail herein. In particular, various aspects of computing systems and specific computer programs to implement the various technical features described herein are well known. Accordingly, in the interest of brevity, many conventional implementation details are only mentioned briefly herein or are omitted entirely without providing the well-known system and/or process details.

In some embodiments, various functions or acts can take place at a given location and/or in connection with the operation of one or more apparatuses or systems. In some embodiments, a portion of a given function or act can be performed at a first device or location, and the remainder of the function or act can be performed at one or more additional devices or locations.

The terminology used herein is for the purpose of describing particular embodiments only and is not intended to be limiting. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, element components, and/or groups thereof.

The corresponding structures, materials, acts, and equivalents of all means or step plus function elements in the claims below are intended to include any structure, material, or act for performing the function in combination with other claimed elements as specifically claimed. The present disclosure has been presented for purposes of illustration and description but is not intended to be exhaustive or limited to the form disclosed. Many modifications and variations will be apparent to those of ordinary skill in the art without departing from the scope and spirit of the disclosure. The embodiments were chosen and described in order to best explain the principles of the disclosure and the practical application, and to enable others of ordinary skill in the art to understand the disclosure for various embodiments with various modifications as are suited to the particular use contemplated.

The diagrams depicted herein are illustrative. There can be many variations to the diagram or the steps (or operations) described therein without departing from the spirit of the disclosure. For instance, the actions can be performed in a differing order or actions can be added, deleted or modified. Also, the term “coupled” describes having a signal path between two elements and does not imply a direct connection between the elements with no intervening elements/connections therebetween. All of these variations are considered a part of the present disclosure.

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e., one, two, three, four, etc. The terms “a plurality” are understood to include any integer number greater than or equal to two, i.e., two, three, four, five, etc. The term “connection” can include both an indirect “connection” and a direct “connection.”

The terms “about,” “substantially,” “approximately,” and variations thereof, are intended to include the degree of error associated with measurement of the particular quantity based upon the equipment available at the time of filing the application. For example, “about” can include a range of ±8% or 5%, or 2% of a given value.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A semiconductor structure comprising:
a first lower transistor and a second lower transistor; and
upper transistors formed above the first and second lower transistors, the first lower transistor comprising a first work function material, the second lower transistor comprising a second work function material different from the first work function material, wherein a portion of the second work function material extends below a bottom surface of the first work function material.

2. The semiconductor structure of claim 1, wherein the upper transistors comprise a third work function material different from the second work function material.

3. The semiconductor structure of claim 1, wherein a gate connector connects one of the upper transistors to the second lower transistor, a part of the gate connector comprising the second work function material.

4. The semiconductor structure of claim 1, wherein a gate connector connects one of the upper transistors to the second lower transistor, the gate connector comprising the second work function material and a third work function material of the one of the upper transistors.

5. The semiconductor structure of claim 1, wherein the second lower transistor comprises a gate dielectric material, an opening being in the gate dielectric material of the second lower transistor.

6. The semiconductor structure of claim 5, wherein the second work function material is disposed in the opening of the second lower transistor.

7. The semiconductor structure of claim 5, wherein the second work function material extends through the opening of the second lower transistor.

8. A method comprising:
providing a first lower transistor and a second lower transistor; and
forming upper transistors above the first and second lower transistors, the first lower transistor comprising a first work function material, the second lower transistor comprising a second work function material different from the first work function material, wherein a portion of the second work function material extends below a bottom surface of the first work function material.

9. The method of claim 8, wherein the upper transistors comprise a third work function material different from the second work function material.

10. The method of claim 8, wherein a gate connector connects one of the upper transistors to the second lower transistor, a part of the gate connector comprising the second work function material.

11. The method of claim 8, wherein a gate connector connects one of the upper transistors to the second lower transistor, the gate connector comprising the second work function material and a third work function material of the one of the upper transistors.

12. The method of claim 8, wherein the second lower transistor comprises a gate dielectric material, an opening being in the gate dielectric material of the second lower transistor.

13. The method of claim 12, wherein the second work function material is disposed in the opening of the second lower transistor.

14. The method of claim 12, wherein the second work function material extends through the opening of the second lower transistor.

15. A method of forming a semiconductor structure, the method comprising:
providing a first lower transistor and a second lower transistor; and
forming upper transistors on a frontside of the semiconductor structure above the first and second lower transistors, the first lower transistor comprising a first work function material, the second lower transistor comprising a second work function material different from the first work function material;
wherein the second work function material is filled from a backside of the semiconductor structure.

16. The method of claim 15, wherein:
the second lower transistor comprises a super-low threshold voltage;
the first lower transistor comprises a medium threshold voltage; and
the upper transistors comprise a high threshold voltage.

17. The method of claim 15, wherein a gate connector connects one of the upper transistors to the second lower transistor, a part of the gate connector comprising the second work function material.

18. The method of claim 15, wherein a gate connector connects one of the upper transistors to the second lower transistor, the gate connector comprising the second work function material and a third work function material of the one of the upper transistors.

19. The semiconductor structure of claim 1, wherein:
the second lower transistor comprises a gate dielectric material, an opening being in the gate dielectric material of the second lower transistor; and
the second work function material is disposed in the opening of the second lower transistor.
